(19) United States
(12) Patent Application Publication
(10) Pub. No.: US 2006/0154460 A1
(43) Pub. Date: Jul. 13, 2006

(54) Self-aligned contact method

(76) Inventors: Serah Yun, Suwon-si (KR); Changki Hong, Seongnam-si (KR); Jaedong Lee, Suwon-Si (KR); Juseon Goo, Suwon-si (KR); Youngok Kim, Suwon-si (KR); Jeongheon Park, Suwon-si (KR); Joonsang Park, Seoul (KR); Keunhee Bai, Suwon-si (KR); Myoungho Jung, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/293,126

(22) Filed: Dec. 5, 2005

(30) Foreign Application Priority Data
Jan. 10, 2005 (KR) 10-2005-0002051

(51) Int. Cl. H01L 21/4763

(52) U.S. Cl. 438/586; 438/675; 438/618

(57) ABSTRACT

In one aspect, a self-aligned contact method is provided in which a substrate having a plurality of structures are spaced apart over a surface of the substrate, and a sacrificial film is deposited over and between the plurality of structures, where a material of the sacrificial film has a given withstand temperature. The sacrificial film is patterned to expose a portion of the substrate adjacent the plurality of structures. An insulating layer is deposited over the sacrificial film and the exposed portion of the substrate, where the depositing of the insulating layer includes a heat treatment at a temperature which is less than the withstand temperature of the sacrificial film material. The insulating layer is planarized to expose the sacrificial film, and the sacrificial film is removed to expose respective areas between the plurality of structures. The respective areas between the plurality of structures are filled with a conductive material.

### BACKGROUND OF THE INVENTION

1. Field of the Invention

The present invention generally relates to the manufacture of semiconductor devices, and more particularly, the present invention relates to self-aligned contact methods utilized in the manufacture of semiconductor devices.

2. Description of the Related Art

Self-aligned contact methods have been adopted to overcome mask alignment problems encountered in the manufacture high-density semiconductor devices. Briefly, such methods are characterized by the use of an oversized mask opening which exposes contact regions bounded by structures aligned within the opening. The contacts formed in these regions are “self-aligned” in the sense that they are defined by the structures rather than the mask opening.

FIGS. 1A through 1G are schematic cross-sectional views for explaining an example of a convention self-aligned contact method.

Referring first to FIG. 1A, an active region 102 is defined between field oxide regions 101 in a semiconductor substrate 100. A plurality of gate structures 110 are spaced apart over the surface of the substrate 100. In this example, two of the gate structures 110 are located over the field oxide regions 101, and the remaining two gate structures are located over the active region 102. Also in this example, each of the gate structures 110 is formed of a stack of a polysilicon layer 104, a tungsten layer 105, and a silicon nitride layer 106.

Gate oxide layers 103 are interposed between the surface of the substrate 100 and gate structures 110 located over the active region 102. Further, sidewall spacers 107 are located on sidewalls of the gate structures 110, and an etch stop layer 108 covers the gate structures 110, the sidewall spacers 107, and exposed surface portions of the substrate 100.

Turning to FIG. 1B, an interlayer dielectric layer 111 is then deposited to cover the gate structures 110 and to fill the gaps between the gate structures 110.

Next, as shown in FIG. 1C, an upper portion of the ILD 111 is removed by chemical mechanical polishing CMP to expose a top surface of the etch stop layer 108.

Referring to FIG. 1D, a photoresist pattern 112 is then formed having an opening A that extends between the two outermost gate structures 110. In other words, one edge of the photoresist pattern is aligned over one of the outermost gate structures 110, while the opposite edge is aligned over the other of the outermost gate structures 110. As such, upper surface portions of the ILD 111 located in contact regions between the gate structures 110 are exposed.

Then, as shown in FIG. 1E, an etching processes is carried out using the photoresist pattern 112 as an etch mask. As a result, the ILD 111 is removed from between the gate structures 110 to define self-aligned contact holes between adjacent pairs of gate structures 110. Also, as a result of low etch selectivity between silicon nitride and the oxide material of the ILD 111, portions of the mask 108 and the silicon nitride 106 of each gate electrode structure 110 are removed.

Referring to FIG. 1F, a conductive layer 113 is then deposited so as to fill the self-aligned contact holes and substantially cover the entire device.

Finally, referring to FIG. 1G, the upper portion of the conductive film 113 (FIG. 1F) is removed by CMP to expose a top surface of each of the gate structures 110. As a result, a plurality of self-aligned contact plugs 114 are formed over the active region 102 and between the adjacent pairs of gate structures 110.

The self-aligned contact process described above suffers certain drawbacks. For example, as shown in FIG. 1E, the gate electrode is generally exposed during dry etching of the dielectric layer 111. As a result, gate leakage may occur as a result of inadvertent dry etching of the sidewall spacers 107.

Also, as illustrated in FIG. 1E, the gate structures 110 located over the field oxide regions 101 have a higher vertical profile than the gate structures 110 located over the active region 102 after removal of the ILD 111. As a result, the CMP of the conductive layer 113 must be conducted for a relatively long time to ensure that the higher portions of the gate structures 110 are removed across the entire wafer. This can result in thinning of the silicon nitride 106 of the gate structures 110 located over the active region 102, which in turn can cause shorts between the conductive plugs 114 and the conductive portions of gate structures 110.

### SUMMARY OF THE INVENTION

According to an aspect of the present invention, a self-aligned contact method is provided in which a substrate having a plurality of structures are spaced apart over a surface of the substrate, and a sacrificial film is deposited over and between the plurality of structures, where a material of the sacrificial film has a given withstand temperature. The sacrificial film is patterned to expose a portion of the substrate adjacent the plurality of structures. An insulating layer is deposited over the sacrificial film and the exposed portion of the substrate, where the depositing of the insulating layer includes a heat treatment at a temperature which is less than the withstand temperature of the sacrificial film material. The insulating layer is planarized to expose the sacrificial film, and the sacrificial film is removed to expose respective areas between the plurality of structures. The respective areas between the plurality of structures are filled with a conductive material.

According to another aspect of the present invention, a self-aligned contact method is provided in which a substrate is provided having a plurality of structures spaced apart over a surface of the substrate, and a sacrificial film is deposited over and between the plurality of structures, where a material of the sacrificial film is non-photosensitive. The sacrificial film is patterned to expose a portion of the substrate adjacent the plurality of structures, and an insulating layer is deposited over the sacrificial film and the exposed portion of the substrate. The insulating layer is planarized to expose the sacrificial film, and the sacrificial film is removed to expose respective areas between the plurality of structures. The respective areas between the plurality of structures are filled with a conductive material.

According to yet another aspect of the present invention, a self-aligned contact method is provided in which a substrate is provided having a plurality of structures spaced apart over a surface of the substrate, and a sacrificial film is deposited over the substrate and between the plurality of structures. A mask pattern is formed over the sacrificial film that is aligned over the plurality of structures, and the sacrificial film is dry etched using the mask pattern as an etch mask to expose a portion of the substrate adjacent the plurality of structures. An insulating layer is deposited over the sacrificial film and the exposed portion of the substrate, and the insulating layer is planarized to expose the sacrificial film. The sacrificial film is removed to expose respective areas between the plurality of structures, and the respective areas between the plurality of structures are filled with a conductive material.

According to an aspect of the present invention, a self-aligned contact method is provided in which a substrate is provided having first and second device isolation regions spaced apart in a surface of the substrate, a first structure located over the first device isolation region, a second structure located over the second device isolation region, and at least one third structure located over the surface of the substrate between the first and second gate structures. A sacrificial film is deposited over the substrate and between the first, second and third structures, and an etch mask is formed over the sacrificial film, where the mask has a first edge that is aligned over the first gate structure and an opposite second edge that is aligned over the second gate structure. The sacrificial film is dry etched using the etch mask as an mask to expose a first surface portion of the substrate adjacent the first structure, and to expose a second surface portion of the substrate adjacent the second structure. An insulating layer is deposited over the sacrificial film and on the exposed first and second surface portions of the substrate, and the insulating layer is planarized to expose the sacrificial film. The sacrificial film is removed to expose respective contact areas located between the first, second and third structures, the respective contact areas between the plurality of structures are filled with a conductive material.

### BRIEF DESCRIPTION OF THE DRAWINGS

The above and other aspects and features of the invention will become readily apparent from the detailed description that follows, with reference to the accompanying drawings, in which:

FIGS. 1A through 1G are schematic cross-sectional views for explaining a conventional self-aligned contact method;

FIG. 2 is a process flowchart for explaining a self-aligned contact method according to an embodiment of the present invention; and

FIGS. 3A through 3G are schematic cross-sectional views for explaining a self-aligned contact method according to an embodiment of the present invention.

### DETAILED DESCRIPTION OF PREFERRED EMBODIMENTS

The invention will now be explained in detail with reference to preferred but non-limiting embodiments of the invention.

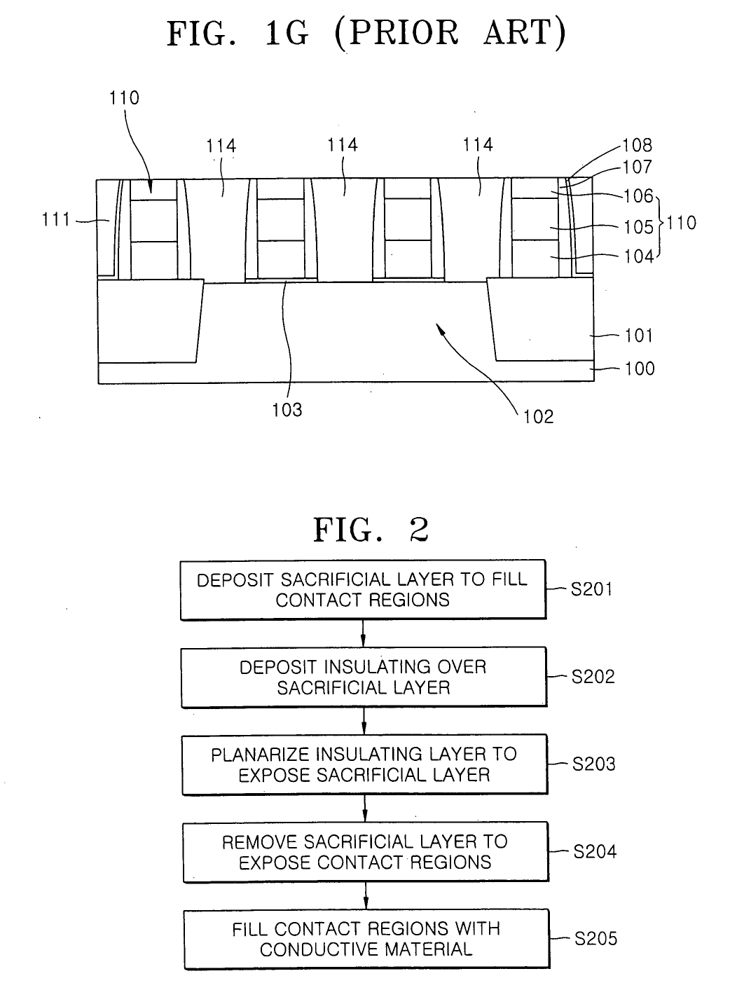

FIG. 2 is a flowchart for use in describing a self-aligned contact method according to an embodiment of the present invention.

Initially, at step S201, a sacrificial layer is patterned to fill contact regions defined between structures spaced apart across the surface of a substrate. The conductive structures may, for example, be gate structures and/or bit line structures of a semiconductor device.

Next, at step S202, a insulating layer is deposited over the sacrificial layer and over exposed portions of the substrate.

Then, at step S203, the insulating layer is planarized to exposed the sacrificial layer, and at step S204, the exposed sacrificial layer is removed to define a plurality of self-aligned contact regions between the structures spaced apart over the surface of the substrate.

Finally, at step S205, the self-aligned contact regions are filled with a conductive material to thereby form a plurality of self-aligned contacts.

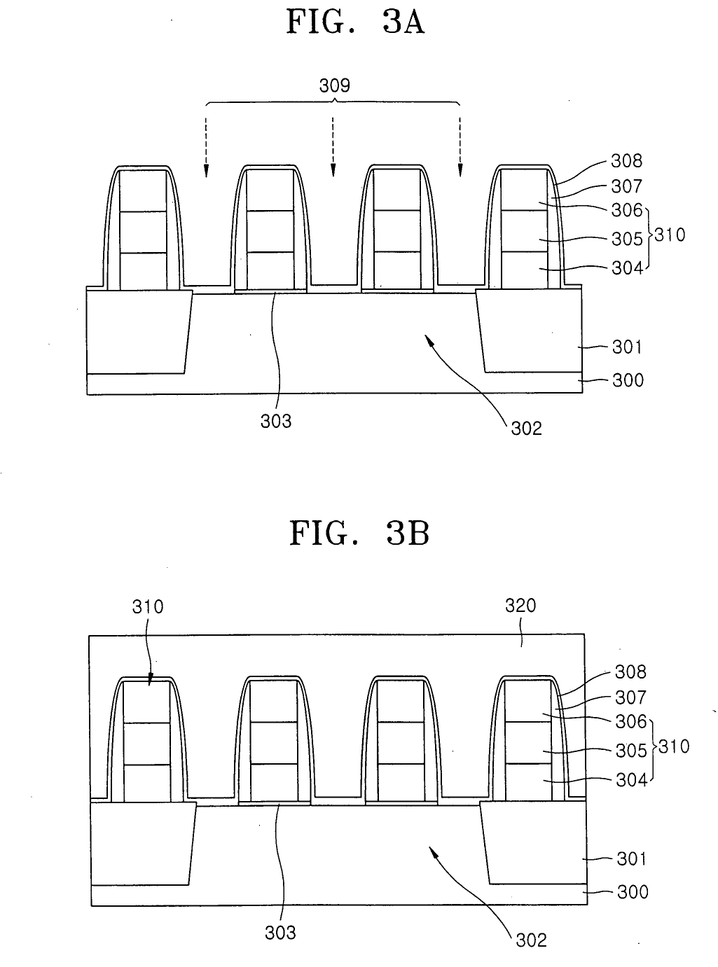

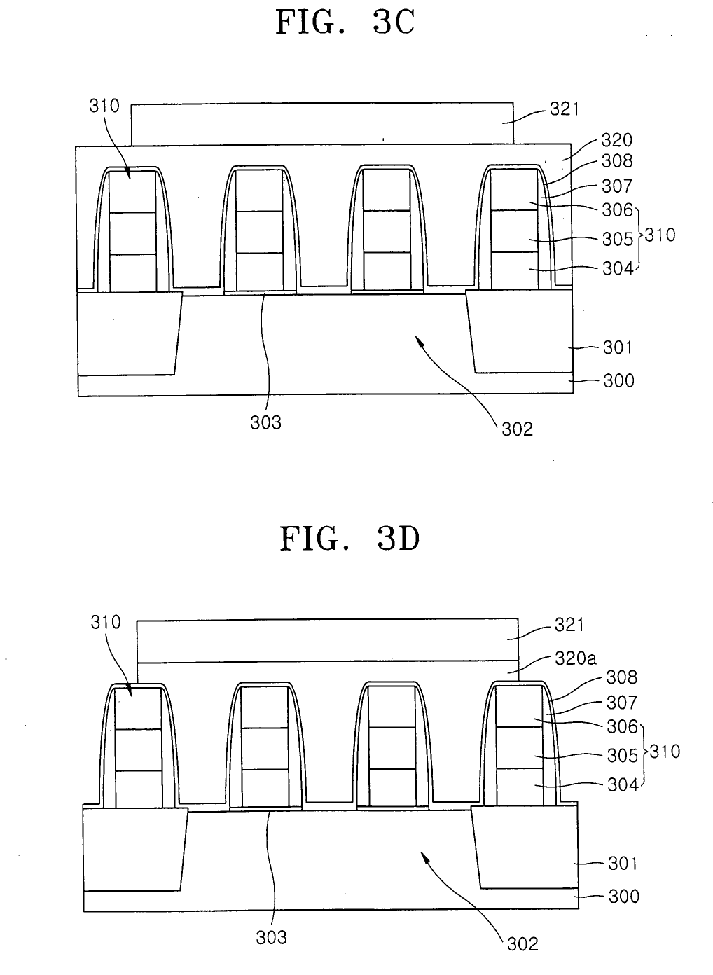

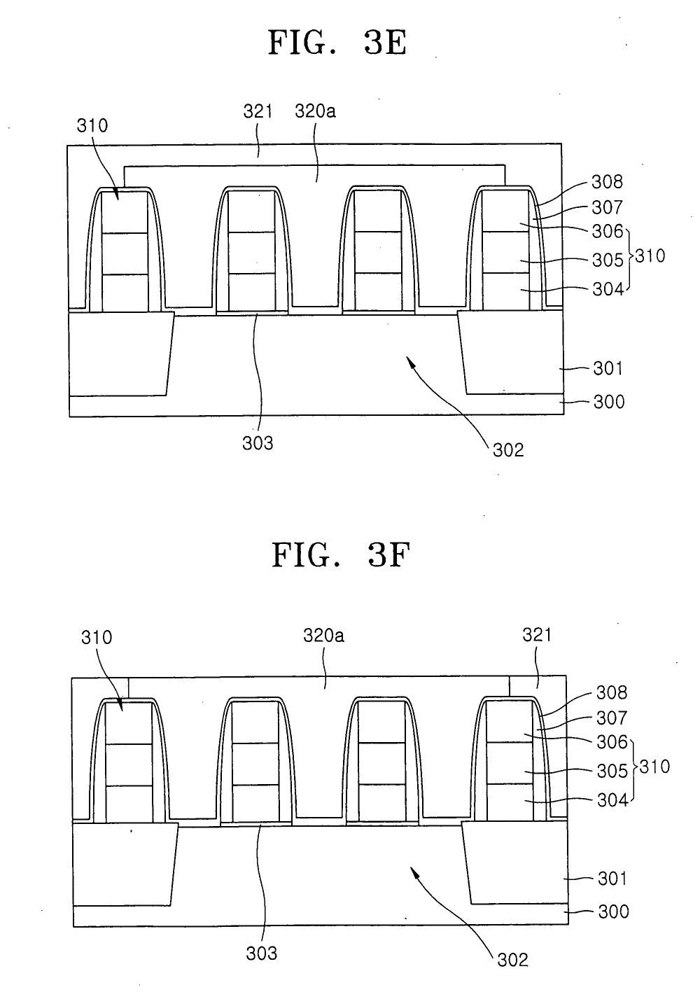

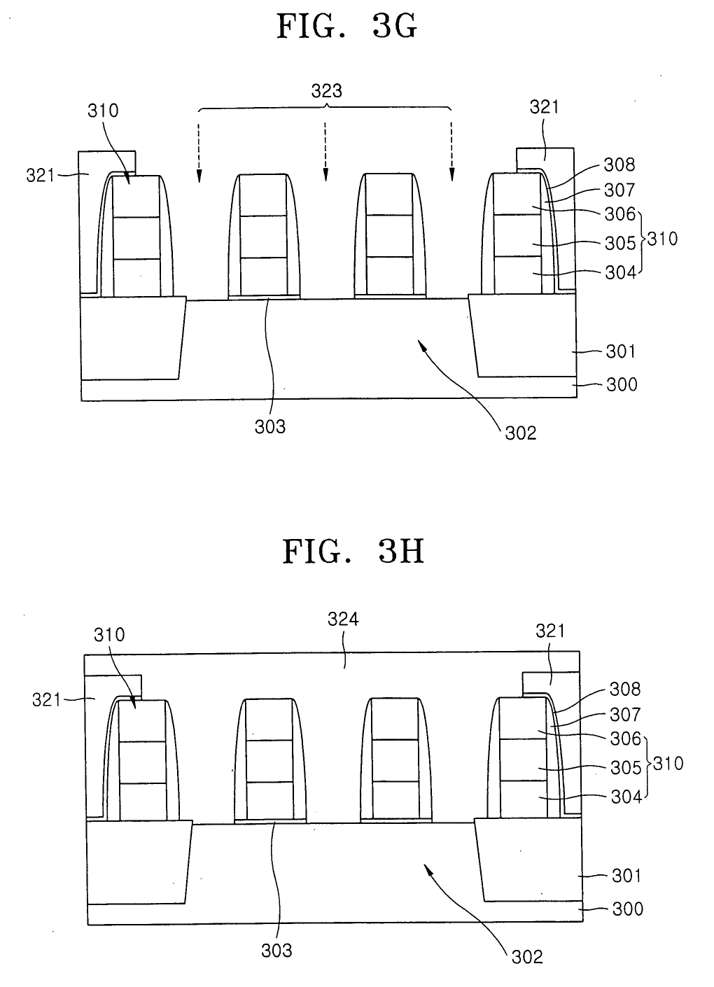

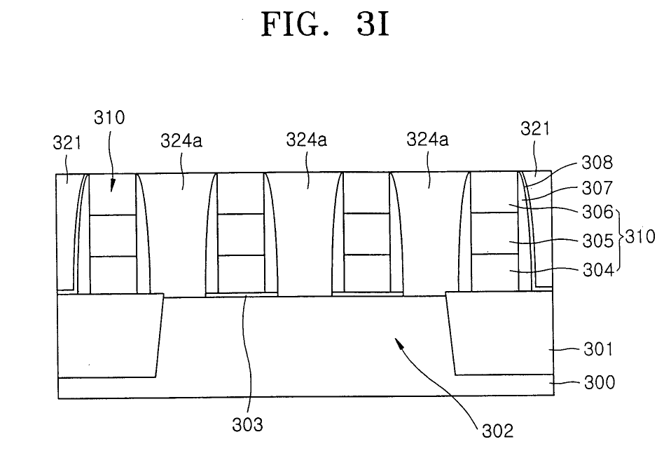

A specific example of a self-aligned contact method in accordance with the present invention will now be described with reference to FIGS. 3A through 3I.

FIGS. 3A through 31 are schematic cross-sectional views for use in explaining a self-aligned contact method of an embodiment of the present invention.

Referring first to FIG. 3A, an active region 302 is defined between field oxide regions 301 in a semiconductor substrate 300. A plurality of conductive structures 310 are spaced apart over the surface of the substrate 300 so as to define a plurality of contact regions 309 between adjacent pairs of the conductive structures 310. In this example, two of the conductive structures 310 are located over the field oxide regions 301, and the remaining two conductive structures 310 are located over the active region 302.

In the example of this embodiment, each of the conductive structures 310 is a gate structure formed of a stack of a polysilicon layer 304, a tungsten layer 305, and a silicon nitride layer 306. As examples only, the polysilicon layer 304 may have a thickness of about 770 Å, the tungsten layer 305 may have a thickness of about 350 Å, and the silicon nitride layer 306 may have a thickness of about 1800 Å. As such, in this example, each of the gate structures 310 has a thickness of roughly 2.9 kÅ.

Gate oxide layers 303 are interposed between the surface of the substrate 300 and gate structures 310 located over the active region 302. Further, sidewall spacers 307 are located on sidewalls of the gate structures 310, and an etch stop layer 308 covers the gate structures 310, the sidewall spacers 307, and exposed surface portions of the substrate 300.

Turning to FIG. 3B, the gate structures 310 are covered with a sacrificial layer 320 so as to fill the contact regions 309 (FIG. 3A) between the gate structures 310. As will become apparent later, preferred properties of the sacrificial layer include good fill characteristics, a high withstand temperature, and favorable CMP and ashing removal characteristics. In this example, the sacrificial layer 320 is a non-photosensitive material having a high withstand temperature, such as a polyarylene ether (PAE) layer or amorphous carbon layer (ACL). Herein, “withstand temperature” is defined as a temperature at which the material deforms, burns, or otherwise becomes unsuitable for its intended purpose. Preferably, the sacrificial layer has a withstand temperature of at least 425° C., and more preferably, the sacrificial layer 320 has a withstand temperature of at least 450° C. PAE has a withstand temperature of about 450° C., and ACL has a withstand temperature of about 600° C.

The thickness of the sacrificial layer 320 is dependent on the thickness of the gate structures 310. In the example given above, where the thickness of the gate structures 310 is roughly 2.9 kÅ, the thickness of the sacrificial layer 320 is preferably greater than about 2.9 kÅ. As an example, the sacrificial layer 320 may be deposited to a thickness of about 4.0 kÅ.

As represented in FIG. 3C, a photoresist 321 is patterned over the sacrificial layer 320 so as to cover the underlying contact regions 309 (FIG. 3A). In this example, one edge of the photoresist 221 is preferably aligned over the leftmost gate structure 310, while the opposite edge of the photoresist 321 is preferably aligned over the rightmost gate structure 310.

Then, as shown in FIG. 3D, a dry etching process is carried out using the photoresist 321 as a mask to remove portions of the sacrificial layer 320 (FIG. 3C) located outside the contact regions 309 (FIG. 3A). As a result, a sacrificial mold layer 320a is defined within the contact regions 309 (FIG. 3A).

Referring to FIG. 3E, after the photoresist 321 (FIG. 3D) is preferably removed, an interlayer dielectric (ILD) layer 321 is deposited over the sacrificial mold layer 320a, the exposed portions of the outermost gate structures 310, and the surface of the substrate 301. Material examples of the ILD layer 321 include HDP, PE-TEOS, BPSG, USG, TOSZ, SOG, and Low-k materials. The ILD layer 321 is preferably deposited to a thickness which is at least as great as that of the gate structures 310. In the example given above, where the gate structures have a thickness of about 2.9 kÅ, the ILD layer 321 is deposited at a thickness which exceeds roughly 2.9 Å. In the example of this embodiment, the ILD layer 321 is deposited to a thickness which is sufficient to cover the upper surface of the sacrificial mold layer 320a. For example, where the thickness of the sacrificial mold layer 210a is about 4 kÅ, the thickness of the ILD layer 321 may be about 6 kÅ.

As will be appreciated by those skilled in the art, the formation of the ILD layer 321 generally includes a heat treatment process to anneal the deposited insulating material. Typically, for example, oxide deposition occurs at a temperature of about 400° C. This is preferably less than the withstand temperature of the sacrificial layer 320, thus avoiding damage to the sacrificial layer 320 during formation of the ILD layer 321.

Referring to FIG. 3F, the ILD layer 321 is subjected to chemical mechanical polishing (CMP) in order to expose the top surface of the sacrificial mold layer 320a. In particular, FIG. 3F illustrates the case where the CMP is halted prior to exposure of the etch stop layer 308 located atop the gate structures 310. However, it is also possible to continue the CMP process until gate structures 310 are exposed, and in fact, some of the silicon nitride 306 may be removed. As will be readily appreciated by those skilled in the art, the structure represented in the drawings is just one of many similar structures that are simultaneously formed across the surface of a wafer. The CMP process should be continued until the sacrificial mold layer 320a is exposed for each of the devices of the wafer. However, height variations across the wafer surface and imperfections in the CMP process may result in different removal amounts of the ILD layer 321. In other words, the CMP process may result in partial removal of the silicon nitride 306 of the gate structure of one device on the wafer, and no removal of the silicon nitride 306 of the gate structure of another device on the same wafer.

Turning now to FIG. 3G, an ashing process is conducted to remove the sacrificial layer 210a (FIG. 2F). As a result, self-aligned contact regions 213 are defined between the conductive structures 310.

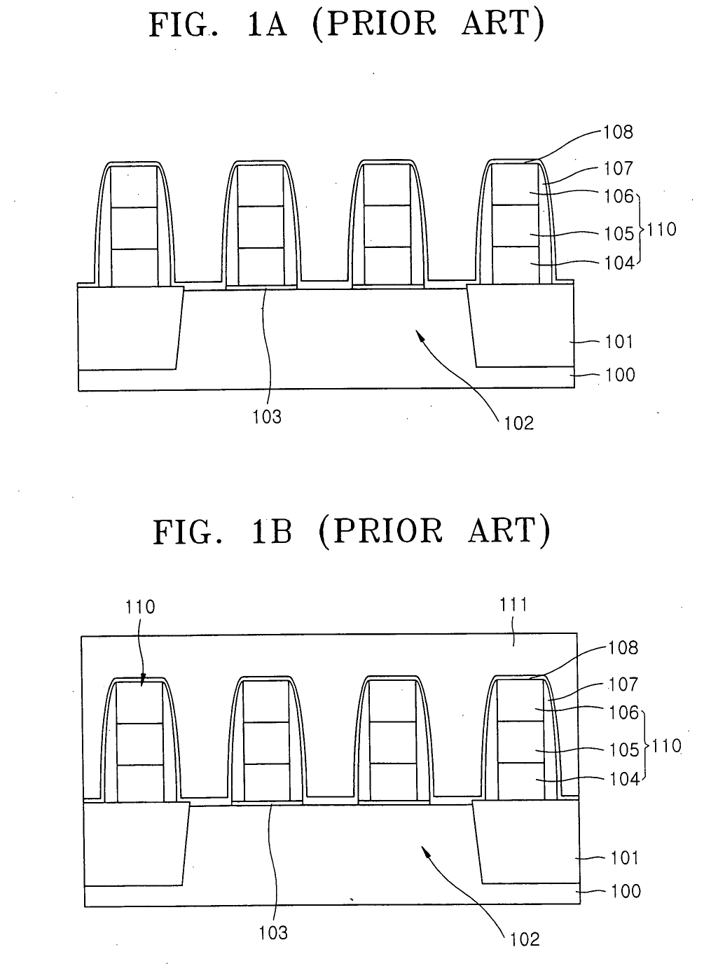

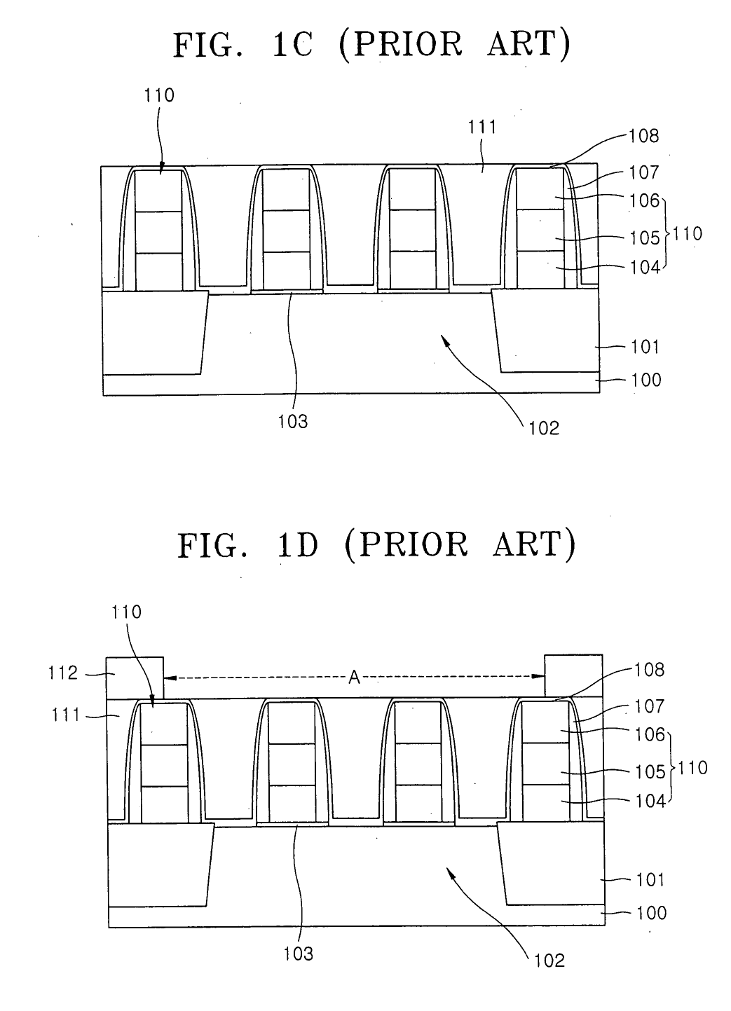

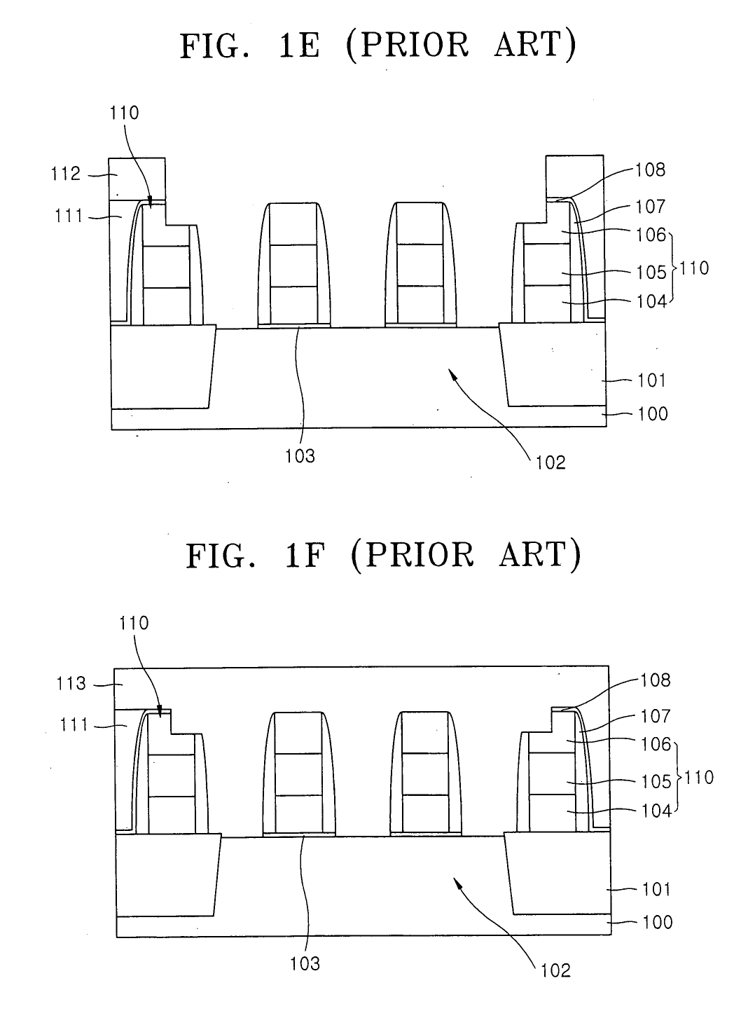

In the example of this embodiment, an ashing process is utilized to remove the sacrificial layer 320a. This is in contrast with the dry etching process of the conventional method to remove the interlayer dielectric layer as described previously in connection with FIG. 1E. As such, the conductive structures 310 are not exposed to a potentially damaging dry etching environment.

Next, as shown in FIG. 3H, the self-aligned contact regions 313 (FIG. 3G) are filled with a conductive layer 324. In the example of this embodiment, the conductive material 314 is a poly silicon material.

Finally, as shown in FIG. 31, the conductive layer 324 (FIG. 3H) is planarized to expose the upper surface portions of the conductive structures 310. In the example of this embodiment, the planarization is conducted by executing a CMP process. As a result, self-aligned contact plugs 324a are formed between the conductive structures 310.

According to the example of the present embodiment, the CMP processes discussed above are conducted under a condition in which all the conductive structures 310 have substantially the same vertical height. This is in contrast with the conventional method described previously in connection with FIG. 1F. As such, excessive exposure of the conductive structures 310 located over the active region 302 to the CMP process is avoided. Less silicon nitride is therefore removed, thus reducing the incidents of shorts between the later formed conductive plugs and the conductive portions of the gate structures.

Although the present invention has been described above in connection with the preferred embodiments thereof, the present invention is not so limited. Rather, various changes to and modifications of the preferred embodiments will become readily apparent to those of ordinary skill in the art. Accordingly, the present invention is not limited to the preferred embodiments described above. Rather, the true spirit and scope of the invention is defined by the accompanying claims.

What is claimed is:

1. A self-aligned contact method, comprising:
providing a substrate having a plurality of structures spaced apart over a surface of the substrate;
depositing a sacrificial film over and between the plurality of structures, wherein a material of the sacrificial film has a given withstand temperature;
patterning the sacrificial film to expose a portion of the substrate adjacent the plurality of structures;
depositing an insulating layer over the sacrificial film and the exposed portion of the substrate, wherein the depositing of the insulating layer includes a heat treatment at a temperature which is less than the withstand temperature of the sacrificial film material;
planarizing the insulating layer to expose the sacrificial film;
removing the sacrificial film to expose respective areas between the plurality of structures; and
filling the respective areas between the plurality of structures with a conductive material.

2. The method of claim 1, wherein the withstand temperature is at least 425° C.

3. The method of claim 1, wherein the withstand temperature is at least 450° C.

4. The method of claim 1, wherein the withstand temperature is at least 425° C., and the heat treatment temperature is less than 425° C.

5. The method of claim 1, wherein the withstand temperature is at least 450° C., and the heat treatment temperature is less than 450° C.

6. The method of claim 1, wherein the sacrificial film material comprises polyarylene ether.

7. The method of claim 1, wherein the sacrificial film material comprises amorphous carbon.

8. The method of claim 1, wherein the structures are gate structures.

9. The method of claim 8, wherein each of the gate structures comprises a nitride layer stacked on at least one conductive layer.

10. The method of claim 1, wherein the sacrificial layer is removed by ashing.

11. The method of claim 1, wherein the structures are bit line structures.

12. The method of claim 1, wherein the filling of the respective areas between the plurality of structures includes chemical mechanical polishing of the conductive material to expose a top surface of the plurality of structures.

13. A self-aligned contact method, comprising:
providing a substrate having a plurality of structures spaced apart over a surface of the substrate;
depositing a sacrificial film over and between the plurality of structures, wherein a material of the sacrificial film is non-photosensitive;
patterning the sacrificial film to expose a portion of the substrate adjacent the plurality of structures;
depositing an insulating layer over the sacrificial film and the exposed portion of the substrate;
planarizing the insulating layer to expose the sacrificial film;
removing the sacrificial film to expose respective areas between the plurality of structures; and
filling the respective areas between the plurality of structures with a conductive material.

14. The method of claim 13, wherein the sacrificial film material comprises polyarylene ether.

15. The method of claim 13, wherein the sacrificial film material comprises amorphous carbon.

16. The method of claim 13, wherein the structures are gate structures.

17. The method of claim 16, wherein each of the gate structures comprises a nitride layer stacked on at least one conductive layer.

18. The method of claim 13, wherein the sacrificial layer is removed by ashing.

19. The method of claim 13, wherein the deposition of the insulating layer includes a heat treatment, and wherein a temperature of the heat treatment is less than a withstand temperature of the sacrificial layer.

20. The method of claim 19, wherein the withstand temperature of the sacrificial layer is at least 425° C.

21. The method of claim 19, wherein the withstand temperature of the sacrificial layer is at least 450° C.

22. The method of claim 13, wherein the filling of the respective areas between the plurality of structures includes chemical mechanical polishing of the conductive material to expose a top surface of the plurality of structures.

23. A self-aligned contact method, comprising:
providing a substrate having a plurality of structures spaced apart over a surface of the substrate;
depositing a sacrificial film over the substrate and between the plurality of structures;
forming a mask pattern over the sacrificial film that is aligned over the plurality of structures;
dry etching the sacrificial film using the mask pattern as an etch mask to expose a portion of the substrate adjacent the plurality of structures;
depositing an insulating layer over the sacrificial film and the exposed portion of the substrate;
planarizing the insulating layer to expose the sacrificial film;
removing the sacrificial film to expose respective areas between the plurality of structures; and
filling the respective areas between the plurality of structures with a conductive material.

24. The method of claim 23, wherein the sacrificial film material comprises polyarylene ether.

25. The method of claim 23, wherein the sacrificial film material comprises amorphous carbon.

26. The method of claim 23, wherein the structures are gate structures.

27. The method of claim 26, wherein each of the gate structures comprises a nitride layer stacked on at least one conductive layer.

28. The method of claim 23, wherein the sacrificial layer is removed by ashing.

29. The method of claim 23, wherein the deposition of the insulating layer includes a heat treatment, and wherein a temperature of the heat treatment is less than a withstand temperature of the sacrificial layer.

30. The method of claim 29, wherein the withstand temperature of the sacrificial layer is at least 425° C.

32. The method of claim 29, wherein the withstand temperature of the sacrificial layer is at least 450° C.

33. The method of claim 23, wherein the filling of the respective areas between the plurality of structures includes chemical mechanical polishing of the conductive material to expose a top surface of the plurality of structures.

34. A self-aligned contact method, comprising:
providing a substrate having first and second device isolation regions spaced apart in a surface of the substrate, a first structure located over the first device isolation region, a second structure located over the second device isolation region, and at least one third structure located over the surface of the substrate between the first and second gate structures;
depositing a sacrificial film over the substrate and between the first, second and third structures;
forming an etch mask over the sacrificial film, wherein the mask has a first edge that is aligned over the first gate structure and an opposite second edge that is aligned over the second gate structure;
dry etching the sacrificial film using the etch mask as an mask to expose a first surface portion of the substrate adjacent the first structure, and to expose a second surface portion of the substrate adjacent the second structure;
depositing an insulating layer over the sacrificial film and on the exposed first and second surface portions of the substrate;
planarizing the insulating layer to expose the sacrificial film;
removing the sacrificial film to expose respective contact areas located between the first, second and third structures; and
filling the respective contact areas between the plurality of structures with a conductive material.

35. The method of claim 34, wherein the sacrificial film material comprises polyarylene ether.

36. The method of claim 34, wherein the sacrificial film material comprises amorphous carbon.

37. The method of claim 34, wherein the first, second and third structures are gate structures.

38. The method of claim 37, wherein each of the gate structures comprises a nitride layer stacked on at least one conductive layer.

39. The method of claim 34, wherein the sacrificial layer is removed by ashing.

40. The method of claim 34, wherein the deposition of the insulating layer includes a heat treatment, and wherein a temperature of the heat treatment is less than a withstand temperature of the sacrificial layer.

41. The method of claim 40, wherein the withstand temperature of the sacrificial layer is at least 425° C.

42. The method of claim 40, wherein the withstand temperature of the sacrificial layer is at least 450° C.

43. The method of claim 34, wherein the filling of the respective areas between the plurality of structures includes chemical mechanical polishing of the conductive material to expose a top surface of the plurality of structures.
